(19) United States
(12) Patent Application Publication
(10) Pub. No.: US 2018/0202039 A1
(43) Pub. Date: Jul. 19, 2018

(54) HEAT TREATMENT METHODS FOR METAL AND METAL ALLOY PREPARATION

(71) Applicant: Honeywell International Inc., Morris Plains, NJ (US)

(72) Inventors: Stephane Ferrasse, Spokane, WA (US); Frank C. Alford, Spokane Valley, WA (US); Susan D. Strothers, Mead, WA (US)

(21) Appl. No.: 15/744,594

(22) PCT Filed: Jul. 12, 2016
(86) PCT No.: PCT/US2016/041859

§ 371 Date: Jan. 12, 2018

Related U.S. Application Data
(60) Provisional application No. 62/194,039, filed on Jul. 17, 2015.

(51) Int. Cl. C23C 14/34; H01J 37/34

(52) U.S. Cl. CPC C23C 14/3414; C22C 9/00; H01J 37/3435

(57) ABSTRACT

The current disclosure includes a method of forming a high strength backing plate for use with a sputtering target comprising solutionizing a first metal material; subjecting the first metal material to equal channel angular extrusion; and aging the first metal material.

### TECHNICAL FIELD

The present disclosure relates to high-strength backing plates, target assemblies, methods of forming high-strength backing plates, and methods of forming target assemblies.

### BACKGROUND

Physical vapor deposition methodologies are used extensively for forming thin films of material over a variety of substrates. One area of importance for such deposition technology is semiconductor fabrication. A diagrammatic view of a portion of an exemplary physical vapor deposition apparatus 10 is shown in FIG. 1. A physical vapor deposition (“PVD”) apparatus 10 comprises a backing plate 12 having a sputtering target 14 bonded thereto. A semiconductive material wafer 18 is within the apparatus 10 and provided to be spaced from the target 14. A surface 16 of target 14 is a sputtering surface. In operation, sputtered material 22 is displaced from surface 16 of target 14 and used to form a coating (or thin film) 20 over wafer 18.

Although monolithic targets are available for some sputtering applications (where monolithic refers to a target formed from a single piece of material and utilized without a backing plate), most targets are joined to a backing plate as depicted in FIG. 1. It is to be understood that the target and backing plate assembly depicted in FIG. 1 is an example configuration since both the target and the backing plate can be any of a number of sizes or shapes as will be understood by those skilled in the art.

Various materials including, but not limited to, metals and alloys are deposited utilizing PVD. Common target materials include, for example, aluminum, titanium, copper, tantalum, nickel, molybdenum, gold, silver, platinum and alloys and combinations thereof. Backing plates are commonly used for most applications involving these materials due to the convenience of mounting in sputtering systems and the ability to provide strength for supporting the target especially under pressures exerted by cooling systems. Target backing plate assemblies can also be less expensive than corresponding monolithic targets.

Conventional backing plates are often formed from copper, copper alloys (e.g. CuCr, CuZn) or aluminum alloys (e.g. Al6061, Al2024). These materials may be chosen due to their thermal electrical and/or magnetic properties. Aluminum alloys can have up to three times lower density than copper alloys but also can have a weaker Young's modulus. Fabrication of conventional aluminum or copper comprising backing plates can include alloy strengthening utilizing, for example, dispersion and precipitation of very fine second phase precipitates. However, these conventional backing plate materials typically have a fairly large grain size, consistently well over 10 microns.

Advances in semiconductor wafer fabrication technology have led to a demand for increasingly large targets, especially for fabrication of 300 mm to 450 mm size wafers. Larger target sizes in turn require higher strength backing plate materials to minimize or avoid target warping. Although many improvements have been made in backing plate materials, increasingly stronger materials are needed to provide sufficient strength for supporting larger target dimensions, especially in view of the increasingly high sputtering power being utilized to improve film quality and uniformity.

Conventional backing plate materials are often of insufficient strength for large targets thereby limiting the size of high quality targets. Conventionally formed backing plates which are thick enough to support relatively large targets are very heavy. The weight of the backing plate can make the target/backing plate assembly and mounting difficult. Finally, conventional backing plate materials often provide poor bond strength when the target is bonded to the backing plate.

It is desirable to develop backing plates and backing plate materials having improved mechanical strength and bonding properties without compromising other physical properties such as bond strength, thermal conductivity, electrical resistivity, eddy current resistance, and thermal stability.

### SUMMARY

In some embodiments, the current disclosure includes a method of forming a high strength backing plate for use with a sputtering target, comprising solutionizing a first metal material at a temperature between about 850 and 950 degrees Celsius; subjecting the first metal material to equal channel angular extrusion; and aging the first metal material at a temperature of between about 400 and about 550 degrees Celsius.

In some embodiments, the current disclosure includes a method of creating a sputtering target backing plate construction, comprising subjecting a first metal compound to solutionizing between about 800 and 950 degrees Celsius for at least one hour; equal channel angular extruding the first metal compound; and aging the first metal compound between about 300 and 550 degrees Celsius for at least 30 minutes.

In some embodiments, the current disclosure includes a sputtering target backing plate composition comprising, a first metal material having a 0.2% offset yield strength greater than 82.5 ksi; and a tensile strength greater than 90 ksi, up to a temperature of at least 425 degrees Celsius.

In some embodiments, the instant disclosure encompasses a high-strength backing plate which has an average grain size of less than 10 microns and has a yield strength of at least 80 ksi.

In some embodiments, the instant disclosure encompasses a method of producing a target backing plate. The method includes performing processing which includes hot forging, solutionizing, and performing severe plastic deformation processing utilizing at least one of equal channel angular extrusion (ECAE), torsion, accumulative roll bonding (ARB), cyclic pressing or extrusion, friction stir welding, corrugative drawing, cryogenic rolling or pressing, and hammer forging. The method optionally includes performing post-deformation processing which uses heat treatment such as annealing, and at least one of rolling and forging. The target backing plate can be created with an average grain size of less than 10 microns and has 0.2% offset yield strength greater than 85 ksi and a tensile strength greater than 90 ksi. Percent offset yield strength and a method of measuring is described in section 7.7.1 of ASTM E8-01.

In some embodiments, the instant disclosure encompasses a target assembly which includes a target and a backing plate. The target includes a first material which has an average grain size of less than about 10 microns. The backing plate comprises a second material which also has an average grain size of less than about 10 microns. The target and backing plate are bonded to each other with a bond having a bond strength of at least 10 ksi.

In some embodiments, the instant disclosure encompasses a method of forming a target assembly. The method includes providing a target and a high-strength backing plate, and joining the target to the backing plate. The target comprises a first material, and the backing plate comprises a second material which has an average grain size of less than about 10 microns. The backing plate may have a 0.2% offset yield strength of at least 85 ksi and may be over 90 ksi. The ultimate tensile strength may be over 90 ksi and may be over 96 ksi. These properties remain valid at material temperatures as high as 400° C. to 450° C.

While multiple embodiments are disclosed, still other embodiments of the instant disclosure will become apparent to those skilled in the art from the following detailed description, which shows and describes illustrative embodiments of the application. Accordingly, the drawings and detailed description are to be regarded as illustrative in nature and not restrictive.

### BRIEF DESCRIPTION OF THE DRAWINGS

FIG. 1 is a diagrammatic view of a portion of a physical vapor deposition apparatus.

FIG. 2 is a flow chart diagram illustrating a method of forming a high-strength backing plate.

FIG. 3 is a cross-sectional view of a material being treated with an equal channel angular extraction apparatus.

FIG. 4 is a graph of the result of treating a material with the present methods, showing the relationship between annealing temperature and hardness.

FIG. 5 is an optical microscopy image of a copper alloy sample taken after being treated with the present methods.

FIG. 6 is a graph of the result of treating a material with the present methods, showing the effect on tensile strength.

FIG. 7 is a graph of the result of treating a material with the present methods, showing the effect of processing temperatures on tensile strength.

FIG. 8 is a graph showing the relationship between the initial solutionizing temperature and the final tensile strength of a copper alloy.

FIG. 9 is a graph showing the relationship between the annealing temperature and the final tensile strength of a copper alloy.

FIG. 10 is a graph showing the relationship between the number of ECAE passes and the final tensile strength of a copper alloy.

FIGS. 11A, 11B, 11C, and 11D are optical microscopy photographs of a copper alloy showing grain size after treatment with the present methods.

FIGS. 12A and 12B are photographs of a copper alloy taken with optical microscopy showing grain size after treatment with the present methods.

FIG. 13 is a graph and list of the grain size distribution in a copper alloy treated with the present methods.

FIG. 14 is a graph and list of the grain size distribution in a copper alloy treated with the present methods.

FIGS. 15A and 15B are graphs showing the misorientation angles in a copper alloy treated with the present methods.

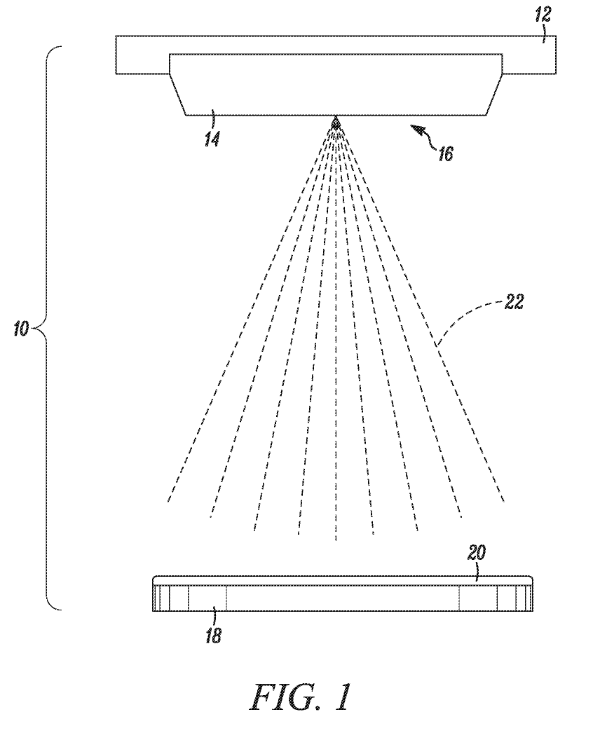

### DETAILED DESCRIPTION

The present methods provide for the production of high strength backing plate materials and backing plates having improved strength and bonding characteristics. Methods of producing high strength backing plate materials, high strength backing plates, and target/backing plate assemblies according to the instant disclosure are also described.

Although high strength monolithic targets have been developed which can be used in certain instances to eliminate problems linked with bonding and bond strength between targets and backing plates, the usefulness of monolithic targets can be limited due to relatively poor strength of high purity target materials used for modern electronic device fabrication. Additionally, monolithic targets can be relatively heavy and expensive as compared to targets which can be bonded to a lighter and/or stronger backing plate material.

Although conventional backing plate materials can be satisfactory for some applications, where large targets are desired and/or where high sputtering power is to be used, high strength backing plate materials can be used to avoid warping and to provide suitable strength to support large target sizes. Further, high strength backing plate materials of the instant disclosure can provide higher bond strength between the target and backing plate.

In general, qualities suitable for modern backing plates for use in advanced sputtering system applications include: high mechanical strength, including Young's modulus and yield strength, which affect target assembly deformation and warping during sputtering; light weight to allow relatively easy handling and mounting; a thermal expansion coefficient comparable or matched to a specific target material to minimize or avoid de-bonding during sputtering; high thermal conductivity for enhanced or optimization of cooling efficiency; composition and physical metallurgical properties that allow for high strength joining and bonding which can preferably produce bond strengths of greater than 10 ksi; and electrical and magnetic properties similar to the specific target material to enhance or optimize magnetic and electrical fluxes during sputtering.

Copper alloys are often used for creating 300 mm backing plates in addition to aluminum alloys, titanium alloys, or steel. Alloys such as CuCr, CuCrNiSi (C18000 grade), and CuZn, are known, but may have mechanical limits for 300 mm targets, which become more severe with larger backing plates, such as 450 mm.

A possible problem of standard Cu alloy backing plates is insufficient strength at high temperature. High temperature mechanical properties are needed for a number of reasons. As an example, depending on target material (e.g. in the case of Ti or Ta), temperatures during sputtering can be very high. Further, higher temperatures are needed for bonding in order to provide sufficient bond strengths. In some materials, temperatures as high as 450° C.-500° C. might be required in order to provide a bond strength that meets a product specification. In another example, diffusion bonded targets with C18000 backing plates may suffer inverse deflection causing the target backside to touch the magnet as well as power fault issues. It is desirable to substantially increase the backing plate strength without adversely impacting other important physical properties. The chosen composition may also impart a good combination of thermal and electrical properties in particular with regards to anti-eddy currents.

In general, a backing plate may have one or more of the following properties: a high mechanical strength including Young's modulus (“E”) and yield tensile strength (“YS”); a coefficient of thermal expansion comparable to that of the target material to avoid mismatch or de-bonding during sputtering; good thermal conductivity for optimal cooling efficiency; and acceptable electrical and magnetic properties, preferably similar to the target material, in order to optimize magnetic and electrical fluxes through the assembly during sputtering.

Backing plate materials and backing plates in accordance with the instant application may include aluminum, an aluminum alloy, copper, or a copper alloy. These materials may provide suitable thermal and electrical conductivity, magnetic properties and coefficient of thermal expansion. This disclosure also encompasses alternative backing plate materials and alloying elements including but not limited to Ag, Al, As, Au, B, Be, Ca, Cd, Co, Cr, Fe, Ga, Ge, Hf, Hg, Ir, In, Li, Mg, Mn, Mo, Ni, O, P, Pd, Sb, Sc, Si, Sn, Ta, Te, Ti, V, W, Zn, Zr, and alloys and combinations thereof. In some embodiments, it is also possible to add dispersed oxides and carbon, for example in the form of carbon nanotubes. Copper, copper alloys, aluminum, or aluminum alloy s used to form backing plates may also contain trace amounts of impurities or other trace materials as well.

An appropriate backing plate material can be chosen based on the material of the sputtering target to which the backing plate will ultimately be joined. Typical sputtering targets for targetkbacking plate assemblies in accordance with the instant disclosure include targets comprising Ag, Al, Be, Co, Cr, Cu, Fe, In, Mg, Mn, Mo, Ni, Sc, Si, Sn, Ta, Ti, V, W, Zn, Zr, and alloys and combinations thereof. The backing plates of the instant disclosure can be joined to the targets using any bonding technique including, but not limited to, soldering, brazing, solid state diffusion bonding, hipping, explosive bonding, hot rolling, and mechanical joining.

Materials which can be used for backing plates in accordance with the instant disclosure include heat-treatable and non-heat-treatable materials, where heat-treatable materials are those that can be hardened by heat treatment, and non-heat-treatable materials are those which are not hardenable and/or can lose strength through thermal treatment. The general methodology and processing in accordance with the instant application can be modified and adapted based upon the heat treatability of the specific material to be utilized for the backing plate.

The methods described herein have been found to substantially improve the strength of existing copper alloy backing plates such as for example those made out of the C18000 composition (available from Weldaloy, Products Co., Warren, Mich.: Nonferrous Products Inc., Franklin, Ind.; or Materion, Corp, Tucson, Ariz.). For example, yield strength, which governs target deflection, has been found to greatly increase when a backing plate material is subjected to these methods.

The present disclosure provides a specific heat treatment sequence combined with severe plastic deformation. In some embodiments, a heat treatment sequence can include a solutionizing and quenching step to solutionize all soluble precipitates, an age hardening step to provide optimal strengthening, and a low temperature recovery annealing to maximize physical properties such as thermal conductivity and electrical resistivity without adversely affecting strength.

In particular instances, the backing plates of the instant disclosure may be used with high strength sputtering targets such as those formed using equal channel angular extrusion (“ECAE”) or other severe plastic deformation techniques. Due to the relatively small grain size in targets produced utilizing ECAE, the high strength backing plate materials of the present disclosure in combination with ECAE targets can produce an increase in bond strength relative to alternative target materials and/or backing plate materials.

It has been discovered that both the solutionizing temperature and the aging temperature are important. In particular, severe plastic deformation may be performed by equal channel angular extrusion (“ECAE”) in between or at the end of the heat treatment steps. ECAE contributes to strengthening by adding dislocations and refining microstructure without detrimentally affecting other physical properties. It has been discovered that there is an unconventional optimum number of passes of ECAE that can be combined with heat treatment to increase the final product strength and contribute additional benefits in some Cu alloys. Additionally, it has been discovered that ECAE can be combined with additional conventional thermomechanical treatment such as rolling to produce a product that possesses superior mechanical properties.

In some embodiments, the methods described in the present disclosure also optimize the thermal conductivity, electrical conductivity, and anti-Eddy currents in a backing plate by providing appropriate heat treatment and processing. Plastic deformation and/or alloying elements contribute to enhancing the electrical resistivity and anti-Eddy current properties. This method can be used to create a backing plate material having an electrical resistivity between 2.5 and 6 μΩ-cm (microOhms-cm), which leads to a superior combination of electrical and thermal properties. Of particular interest for sputtering target applications are the CuCrNiSi alloys. As previously described. C18000 is an example of such an alloy and contains a typical range of about 1.8 to 3.5% of Ni. This moderate quantity increases the electrical resistivity to a range of about 3 to 4 μΩ-cm, which is acceptable.

The material that will undergo the methodology described in the present disclosure may also be chosen for suitable high thermal stability and/or high strength. For example, if it is desired to form a copper backing plate using the enclosed methodology, a copper alloy may form the initial alloy material and additional elements may be added to the copper alloy to impart thermal stability in the final copper backing plate. Examples of elements that may be added to the copper are Ti, Ni, and Co, which have been used to improve thermal stability in copper alloys.

An additional strategy when choosing a copper alloy is to add specific elements for the purpose of adding strength. Copper alloys for backing plates may include alloying elements that add strength to the alloy. For example, a copper alloy backing plate may comprise at least one of Ni, Cr, Si, Fe, Be, Zr, Ag, Mg, Mn, Nb, V, Co, Sc, Sn, Al, Zn, W, and combinations thereof, Zr, Fe, Be, Mg, Sn, Nb, Sc, Ag, Mn, V, Co, Zn, Zr, Be, Cr, W, and Ni are of particular interest as they can form precipitates. It is also possible to add dispersed oxides and carbon (e.g., carbon nanotubes). Typical quantities may be weight percentages as low as 0.1%, 0.25%, or 0.5%, or as high as 1%, 2%, or 5% or may be within a range delimited by a pair of the foregoing values, such as 0.1% to 5%, 0.25% to 2%, or 0.5% to 1%. In some embodiments, the copper backing plate may include between about 1.5 wt % and 6.0 wt % nickel, between about 0.25 wt % and 2.0 wt % silicon, between about 0.10 wt % and 2.0 wt % chromium, and the balance copper. For example, the copper backing plate may include nickel in a weight percentage of from about 1.5 wt % to 6.0 wt %, from about 1.75% to about 4.5%, from about 2.0% to about 3.0%, or about 2.5%. Copper or copper alloys used to form backing plates disclosed herein may also include impurities and/or trace materials.

Some elements have a varying degree of solid solubility in copper, which changes as the temperature increases. This makes it possible to form the so-called age- or precipitation-hardened alloys using a solutionizing step as described herein. Specifically, some alloying elements exhibit higher solubility in solid copper when hot than when cold.

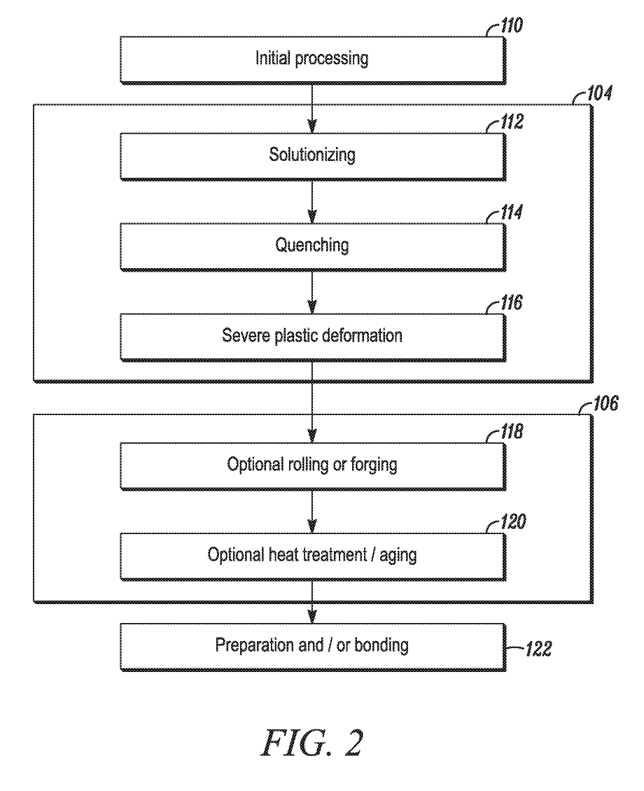

In general, the methodology for processing of heat-treatable and non-heat treatable materials in accordance with the instant disclosure can typically include casting an ingot of material, preliminary thermal processing, and extruding using equal channel angular extrusion. The general processing can also, in some instances, use annealing at one or more stages of processing of the material. The described methodology can be used for forming high strength backing plates, high strength backing plate materials and backing plate/target assemblies in accordance with the instant disclosure. [001] The methodology of the process is described generally with reference to FIG. 2. An exemplary processing scheme for treating aluminum alloys, copper, or copper alloys is shown. The outlined process shown in FIG. 2 can be used for both heat-treatable and non-heat-treatable alloys. Heat-treatable alloys can optionally undergo additional processing treatments.

In some embodiments, the alloy material may undergo an initial processing step 110 to produce the starting material in a desired form, such as a particular size or shape, for use in the current method. The initial processing step 110 can comprise, for example, one or more of casting or forging, such as hot-forging. Hot-forging can comprise a single heating or can comprise an initial heating and one or more subsequent reheating events. The height reduction produced during each forging event between the initial heating and each subsequent reheating can vary depending on factors such as the particular composition and forging temperature used. The initial processing step 110 of the instant disclosure is not limited to particular homogenizing and/or hot-forging treatments, or treatment sequences. In particular aspects, an initial processing step 110 can comprise homogenizing of a cast material followed by hot-forging.

Following the initial processing step 110, the starting material is then subjected to the optimizing heat treatment process shown in FIG. 2 as process 104. The optimizing heat treatment process 104 begins with a solutionizing step 112 applied to the initial alloy material to homogenize precipitates within the initial material. Solutionizing 112 can be conducted at a temperature sufficient to induce solutionization and homogenization in the particular composition being treated. The solutionizing 112 temperature can preferably be maintained for time sufficient to maximize the solutionization of the composition. During solutionizing 112, alloying elements with a higher solubility at high temperature are dissolved into the main matrix of the initial material and put into solid solution. If those elements are in precipitates, this means that those precipitates also diffuse and dissolve into the initial material main matrix.

In some embodiments, solutionizing 112 of aluminum materials comprises solutionizing 112 at a temperature of above about 400° C. for a time period of up to 1 hour, or for at least about 1 hour. For heat-treatable aluminum alloys, solutionizing 112 can be conducted at a temperature of between 450° C. and 650° C., between about 500° C. and 650° C., and between about 550° C. and 650° C., for a time period of up to 1 hour or greater than 1 hour. In some embodiments, solutionizing 112 can be conducted for between 1 and 8 hours, or for greater than 8 hours and up to 24 hours.

Where the material is a heat-treatable copper or copper alloy, solutionizing 112 may be conducted at a temperature of between about 500° C. and 950° C. for a period of up to 1 hour, or for over 1 hour. In some embodiments, for heat-treatable copper alloys, solutionizing can optionally be conducted at a temperature of between 500° C. and 950° C., between about 600° C. and 950° C., between about 700° C. and 950° C., between about 800° C. and 950° C., or between about 850° C. and 950° C. for a time period of up to 1 hour, or for greater than 1 hour. In some embodiments, for heat-treatable copper alloys, solutionizing can optionally be conducted at a temperature of from about 875° C. to about 950° C., from about 890° C. to about 950° C., or from about 900° C. and 940° C. In some embodiments, solutionizing 112 of copper materials comprises solutionizing 112 at a temperature of above about 850° C. for a time period of at least about 1 hour. In some embodiments, solutionizing 112 can be conducted for between 1 and 8 hours. In some embodiments, solutionizing 112 can be conducted for greater than 8 hours and up to 24 hours.

In some embodiments, solutionizing 112 is followed by a quenching step 114 in either water or oil. In quenching step 114, the solutionized material is rapidly cooled from the solutionizing temperature to below the plastic deformation temperature of the material. As used herein, the term “rapidly cooled” is defined as cooling at a rate fast enough to create a supersaturated solid solution before the material has had time to reform into grains of undesired sizes.

It is to be noted that temperatures sufficient for the solutionizing or homogenizing step 112 may result in grain growth producing a grain size above the desired ultimate grain size for the backing plate material. Accordingly, conventional methods which attempt to achieve smaller grain sizes tend to minimize the solutionizing or homogenizing treatments. However, the methodology according to the present disclosure allows post solutionization reduction in grain size and can thereby achieve the benefits of both the solutionizing treatment and small grain size. It can be advantageous to solutionize 112 to dissolve any precipitates and/or particles present in the initial material. Solutionizing 112 can additionally decrease or eliminate chemical segregation within the material being processed.

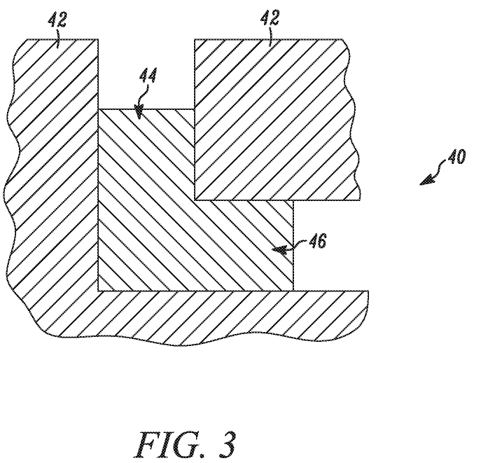

In some embodiments, after solutionizing 112 and quenching 114, the hot-forged material can subsequently undergo severe plastic deformation processing 116. In a preferred embodiment, severe plastic deformation 116 uses equal channel angular extrusion (ECAE). Referring to FIG. 3, an exemplary ECAE device 40 includes a mold assembly 42 that defines a pair of intersecting channels 44 and 46. The intersecting channels 44 and 46 are identical or at least substantially identical in cross-section, with the term “substantially identical” indicating the channels are identical within acceptable size tolerances of an ECAE apparatus. In operation, a preliminary treated material (which can be the solutionized material described above) is extruded through channels 24 and 26. Such extrusion results in plastic deformation 116 of the material by simple shear, layer after layer, in a thin zone located at the crossing plane of the channels. Although it can be preferable that channels 44 and 46 intersect at an angle of about 90°, it is to be understood that an alternative tool angle can be used (not shown). The tool angle (channel intersect angle) of about 90° is typically used to produce an optimal deformation (true shear strain).

ECAE can introduce severe plastic deformation in the solutionized material while leaving the dimension of the block of material unchanged. ECAE can be a preferred method for inducing severe strain in a metallic material in that ECAE can be used at low loads and pressures to induce strictly uniform and homogenous strain. Additionally. ECAE can achieve a high deformation per pass (true strain ε=1.17); can achieve high accumulated strains with multiple passes through an ECAE device (at n=4 passes, ε=4.64); and can be used to create various textures/microstructures within materials by using different deformation routes (i.e. by changing an orientation of the forged block between passes through an ECAE device.)

The material being processed by ECAE can be passed through the ECAE apparatus several times and with numerous routes. A preferred route to use when the material is subjected to multiple passes through the ECAE apparatus 40 can be the “route D.” Route D refers to a method of constantly rotating the block of material 90° in the same direction between each successive pass. Thus using route D, a block with a square cross sectional area will undergo one complete rotation after 4 successive passes, as opposed to, for example, inserting the block using the same orientation for each pass, or rotating the block 180° for each successive pass.

In some embodiments, ECAE processing in accordance with the present disclosure is limited to one pass. In other embodiments, the ECAE processing will preferably include at least one or two passes in order to produce a sub-micron structure, where sub-micron structure refers to a structure having an average grain size of less than 1 micron. In some embodiments, ECAE processing will include between four and six passes.

During ECAE processing, the extrusion can be conducted either at a cold or a hot processing temperature. The processing temperature may be achieved by heating the ECAE die during ECAE processing. Alternatively or in addition to heating the die, the material being extruded may be heated during an annealing step between each successive pass. Where an annealing step is used in between passes, or where the ECAE die is heated for the ECAE, the annealing or die temperatures used are preferably less than a temperature which would cause an increase in grain size over 1 micron for the particular material being processed. This relationship between the temperature and grain size is discussed further below.

For copper or copper alloys, where heating is conducted during ECAE passes and/or during one or more intermediate annealing step, the heating temperature may be as low as 25° C. or 200° C., or as high as 450° C. or 550° C., or may be within a range delimited by a pair of the foregoing values, such as between 25° C. and 550° C., between 200° C. and 500° C., or between 200° C. and 450° C.

The ECAE process, along with the described thermo-mechanical heat treatments, can be used to refine the microstructure of backing plate materials to produce an average grain size of less than or equal to about 10 microns and in particular instances can produce an average grain size of less than about 1 micron. These exceedingly small grain sizes can dramatically increase the yield strength of material relative to conventional backing plate materials which typically have a grain size of well over 10 microns. A typical increase in yield strength of material processed in accordance with the disclosure is at least 1.5 times the yield strength of the same material processed by conventional methods. In particular instances the increase in yield strength can be from about 2 to about 5 fold relative to the yield strength of conventional materials. The increase in strength of backing plates produced in accordance with the methodology disclosed here can also allow backing plates to be made thinner to support a given target relative to conventional backing plates. High strength backing plate materials can inhibit or prevent target warping and can additionally assist solid state diffusion bonding between the backing plate and target.

In addition to strengthening backing plate materials, equal channel angular extrusion or alternative severe plastic deformation techniques can substantially increase the coefficient of diffusion along grain boundaries relative to conventionally processed materials. The enhanced diffusion properties equate to a greater efficiency for bonding at a given set of conditions (temperature, time, and pressure) relative to conventionally processed materials. Thus, a lower bonding temperature can be used than that required for bonding conventional materials, while equivalent bond strength can be achieved. This decreased bonding temperature can limit grain growth in both the target and the backing plate during the bonding processing. Accordingly, the target and backing plate materials are better able to retain the strength imparted by the fine grain size of the materials, particularly in instances where both the backing plate material and target materials have grain sizes of less than 10 microns and in particular instances less than 1 micron producible by ECAE methodology.

Producing target backing plates in accordance with the current disclosure using solutionizing 112 in combination with ECAE can be especially advantageous for non-heat-treatable alloys (those whose strength is not increased by thermal treatments such as aging). ECAE plastic deformation of non-heat-treatable alloys can strengthen such materials by grain refinement to produce a sufficiently high strength without the need for aging (discussed below). Similarly, using the methods of the current disclosure that include ECAE can allow higher purity materials to be used for backing plates since the described processing can impart sufficient strength for these highly pure materials to be used as a backing plate. Prior to the methodology described herein, high purity materials were typically avoided for backing plate applications since an absence or low level of alloying element did not sufficiently provide dispersion or precipitation strengthening for backing plate applications.

Although the severe plastic deformation step 116 is described as comprising equal channel angular extrusion, alternative plastic deformation techniques can be used individually or in addition to equal channel angular extrusion. Exemplary alternative plastic deformation techniques include torsion, accumulative roll bonding (ARB), cyclic pressing or extrusion, friction stir welding, corrugative drawing, cryogenic rolling or pressing, hammer forging and related techniques.

In some embodiments, after severe plastic deformation 116, post-plastic deformation processing 106 can be conducted. Post-plastic deformation processing 106 can optionally comprise one or both of rolling and forging 118. The forging and/or rolling 118 is generally conducted to produce a total reduction of between about 50% and less than 90% to achieve a final backing plate thickness. For example, the forging and/or rolling 118 can be conducted to produce a total reduction of between about 80% and less than 90% to achieve a final backing plate thickness. Machining and or other shaping techniques can be used either independently or in combination with forging and/or rolling 118.

The post deformation processing 106 can optionally comprise an additional heat treatment step 120. For example, an additional heat treatment step such as aging 120 may be used. In addition to the processing used for non-heat-treatable alloys, processing of heat-treatable alloys in accordance with the instant disclosure can additionally comprise one or more aging steps 120. The aging step 120 can be performed before ECAE, after ECAE and/or between ECAE passes. Where rolling and/or forging 118 is used, the aging step 120 can be conducted either prior to or after such rolling/forging 118 processes.

An aging step 120 of heat-treatable materials typically comprises heating the material to a suitable temperature and holding it at that temperature for a given period of time. The aging step 120 can be carried out in a single heating treatment, or in multiple treatments. The aging step 120 of copper or copper alloys of the current disclosure can typically comprise one or more aging treatments at temperatures as little as 100° C., 200° C., or 300° C., or as high as 500° C. or 550° C., or within a range delimited by a pair of the foregoing values, such as between 100° C. and 550° C., between 300° C. and 550° C., or between 400° C. and 500° C. In some embodiments, the aging step 120 may be carried out at a temperature of from about 430° C. to about 470° C., from about 440° C. to about 460° C., or from about 445° C. to about 455° C. Depending on the material being processed and the desired outcome, the aging step 120 may be carried out for up to 30 minutes, at least 30 minutes, for over 1 hour, between 1 and 8 hours, or alternatively up to 24 hours.

Aging of heat-treatable materials in accordance with the current disclosure can comprise either peak aging or over aging conditions, where peak aging refers to aging at a temperature for a length of time for maximum production of very small precipitates. Upon achieving peak aging, the material being processed is preferably cooled to prevent over aging since over aging can result in precipitate coalescence or enlargement, thereby decreasing the strength of the material. Typically peak aging is a preferred embodiment, but over aging is also contemplated in some methods.

Aging can be used to produce uniformly dispersed fine precipitates and, where peak aging is formed, precipitates can preferably have a maximum diameter of less than 1 micron or less than 0.5 micron to achieve optimal strengthening. In heat-treatable materials, the combination of grain refinement by equal channel angular extrusion and formation of exceedingly fine precipitates by aging can have a cumulative strengthening effect. Additionally, aging 120 can increase the thermal stability of the sub-micron grain structures due to the effect of pinning the fine precipitates present at the grain boundaries of the sub-micron grains.

Alternatively or in addition to heat treatment with an aging step 120, an annealing treatment such as, for example, recovery annealing may be included. Where recovery annealing is included in the processing, the recovery annealing is preferably conducted at a temperature and for a time insufficient to induce grains to grow over 10 microns. However, in particular instances it is preferable that the recovery annealing maintains a grain size of less than or equal to 1 micron. In other words, post-plastic deformation annealing is preferably conducted under conditions insufficient to result in static recrystallization of the corresponding material. It can be advantageous to include recovery annealing after a plastic deformation step 116 to reduce defects and free energy present at grain boundaries particularly in materials having submicron grain sizes. Recovery annealing can be used for release of internal stresses and optimization of properties such as ductility and/or conductivity.

It is noted that both annealing and aging are heat treatments. Annealing is a more general heat treatment than aging that is specifically geared toward optimizing precipitates size and distribution. However, in the context of this disclosure, typically an aging treatment is done first, and additional annealing can be done at temperatures lower than that of peak aging conditions to release stresses or modify some electrical properties by changing the grain size without affecting precipitate sizes and distribution. Annealing conditions may be controlled to remain lower than those of peak aging to maintain a maximum strength.

Recovery annealing of copper and copper alloy materials can typically use temperatures as low as 100° C., 200° C., or 300° C., or as high as 500° C. or 550° C., or within a range delimited by a pair of the foregoing values, such as between 100° C. and 550° C., between 300° C. and 550° C., or between 400° C. and 500° C. for at least 1 hour. Additional annealing parameters that can be used with the present embodiments are described below.

Upon completion of post-deformation processing 106, the method can proceed to preparation and bonding of the resulting backing plate to a sputtering target to produce a target/backing plate assembly. A bonding step 122 can include preliminary surface preparation such as cleaning, machining and/or electroplating. Where preliminary surface treatment includes machining, the machining can include, for example, machining grooves in the backing plate surface which will ultimately be bonded to the target. Such machine grooves can help diffusion processes during target-backing plate joining. Additionally, in particular instances, preliminary surface treatment prior to bonding 122 can include providing an insert to enhance the backing plate assembly's bonding ability and/or bond strength. Insert materials can comprise, for example, Ag, Al, Ni or Cu.

Upon completion of any preliminary surface treatment, the resulting backing plate can be bonded 122 to a target by using any of a number of bonding techniques. Bonding 122 can comprise low temperature or high temperature bonding depending upon the particular backing plate material and target material to which the backing plate is to be bonded. Exemplary bonding techniques which can be used for bonding 122 the backing plate materials include, but are not limited to, soldering, brazing, solid phase bonding, hot rolling, mechanical joining, roll cladding, friction stir welding, hot isostatic pressing, explosion bonding, and mechanical joining techniques. In particular instances, solid phase bonding can be used, where solid phase bonding refers to bonding between a target and a backing plate while both the target and backing plate materials remain in their solid phase. Solid phase bonding can produce diffusion bonding to occur along a bonding interface without affecting the microstructure and precipitates of the target and backing plate materials. The solid phase bonding can be performed using insert material as described above. Alternatively, one or more of electroplating, ionization, or surface machining can be used to enhance diffusion bonding processes and the strength of the resulting bond.

Target/backing plate assemblies produced in accordance with the methodology of the present disclosure can typically have a bond strength of at least about 10 ksi. In some embodiments, bonds strengths between backing plates of the disclosure and sputtering targets may exceed 30 ksi, with the strongest bonds being formed where both the target and the backing plate have submicron grain sizes.

The methodology described here has been shown to yield backing plate material having an average grain size of less than 10 microns, a 0.2% offset yield strength greater than 82.5 ksi, and an ultimate tensile strength greater than 90 ksi. In some embodiments, the methods disclosed herein may provide a backing plate having a 0.2% offset yield strength of at least 80 ksi and may be over 90 ksi. In some embodiments, the ultimate yield strength may be from about 82.5 ksi to about 105 ksi, from about 85 ksi to about 100 ksi, or from about 90 ksi to about 95 ksi

In some embodiments, the methods disclosed herein may provide a backing plate having an ultimate tensile strength over 80 ksi and may be over 95 ksi. In some embodiments, the ultimate tensile strength may be from about 80 ksi to about 105 ksi, from about 85 ksi to about 100 ksi, or from about 90 ksi to about 95 ksi. The current methodology may be used to form backing plates with these mechanical properties, stable up to temperatures of at least 425° C. to 500° C. Materials with these properties allow for high temperature bonding of the materials for a wide range of sputtering target application

The methodology of the present disclosure can also be used to produce backing plates from heat-treatable materials with increased strength and bonding properties relative to backing plates produced by conventional methods. Processing of heat-treatable materials in accordance with these embodiments can in general include all of the processing steps discussed above with reference to FIG. 2. It is noted that processing of heat-treatable aluminum alloys, copper, and copper alloys in accordance with these embodiments typically includes a solutionizing treatment in the initial processing step 110.

The described methods can be used for producing backing plates from any desired heat-treatable or non-heat-treatable backing plate material. In particular instances, backing plate materials can be aluminum, aluminum alloy, copper, or copper alloy materials. These aluminum and copper materials can be particularly useful as backing plate materials due to their thermal and electrical conductivities and magnetic properties. Exemplary backing plate materials which can be processed to produce high strength backing plates in accordance with the present application include aluminum or copper alloys comprising aluminum or copper as the primary constituent and from about 0.05% to about 15%, by mass, of one or more alloying elements selected from the group consisting of Cd, Ca, Au, Ag, Be, Li, Mg, Cu, Pd, Hg, Ni, In, Zn, B, Ga, Mn, Sn, Ge, W, Cr, 0, Sb, Ir, P, As, Co, Te, Fe, S, Ti, Zr, Sc, and Hf. In particular instances, preferred alloying elements can be selected from Si, Mn, Mg, Fe, Li, Cu, Zr, Zn, V, Sc, Ti and Cr. The aluminum or copper alloys may have aluminum or copper as the primary constituent and one or more of these alloying elements and/or trace impurities.

Activation energy values for grain boundary diffusion of conventional materials and aluminum, copper, and copper alloy materials of the instant disclosure are set forth in Table 1. As shown in Table 1, copper materials and copper alloy materials subjected to ECAE treatment in accordance with the present disclosure have activation energies decreased approximately 1.5 times relative to conventional materials. Aluminum alloys processed in accordance with the present embodiments including ECAE show a decrease in activation energy of about 2-3 times relative to conventional alloys or pure aluminum. Results similar to those presented in Table 1 were obtained for additional copper and aluminum alloys processed in accordance with the methods described above. The low activation energy corresponds to an increase in coefficient of diffusion by approximately 1.5-6 orders of magnitude. This is indicative of a high atomic mobility of non-equilibrium grain boundaries of materials processed using equal channel angular extrusion.

TABLE 1
Activation Energies for Grain Boundary Diffusion (Q_{GB})

| | | Cu 0.5% | |
|---|---|---|---|
| Material | Pure Copper | Sn by weight | Al (Al6061) |
| ECAE processed | Q_{GB} = | Q_{GB} = 85 kJ/mol | Q_{GB} = 28 kJ/mol |
| (ave grain <1 μm) | 78 kJ/mol | | |
| Commercial | Q_{GB} = | Q_{GB} = 111 kJ/mol | Q_{GB} = 88 kJ/mol |
| (ave grain >10 Jim) | 1 07 kJ/mol | | |

In an exemplary process, the materials listed are subjected to a solutionizing treatment from 850° C. up to 950° C. for over 1 hour, and in some cases preferentially over 8 hours. Following the solutionizing, the material is rapidly quenched in oil or water.

The quenched material is subjected to ECAE, preferentially limited to 1 pass or 2 passes for best strength. It is preferable not to exceed 4 passes. It has been found that an excessively high number of passes facilitates the decomposition of second phases back into solution which is detrimental to the material's ultimate strength. Rolling is preferentially performed after ECAE especially after completing 1 ECAE pass. During rolling, the optimal deformation range for rolling is between 50% and up to 95% height reduction. The best practical range for rolling has been found to be between 60% and 90% reduction. An aging treatment may be performed after either the ECAE step or the ECAE and solutionizing heat treatment step. It has been found that an optimal temperature range for the aging step is between 400° C. up to 550° C. for at least 30 min. and may be between 1 and 8 hours. The longer aging times are used especially for thick plates (i.e. greater than 0.5 inch thick).

The finished backing plate material can be bonded to a sputtering target. The bonding may be done preferably at a temperature that does not adversely affect the material strength of the backing plate. A suitable temperature may be less than 550° C., and preferentially less than 500° C. In some embodiments, bonding can replace or be carried out simultaneously with the aging step. For example, if diffusion bonding is used, the time and temperature used for bonding can be selected from suitable aging times and temperatures. Using this process, materials comprising very fine micro-structures with submicron sizes and multiple dislocations pinned by fine precipitates and optimal angle boundaries have been produced.

### EXAMPLES

The following non-limiting Examples illustrate various features and characteristics of the present disclosure, which is not to be construed as limited thereto.

### Example 1—Effect of ECAE in Combination with Precipitation Hardening and Low Temperature Aging in C18000

A billet of C18000 material was used as the starting material. It was processed using standard heat treatment, forging, and rolling techniques by the supplier Weldaloy, Products Co., located in Warren, Mich. The composition of the main elements, as tabulated in Table 2 was 96.94% Cu, 2.20% Ni, 0.48% Si, 0.37% Cr, less than 0.01% Fe, and the remaining 0.004% constituted trace elements. The original grain size was fairly non uniform, ranging from 33.75-52.5 μm at the edge to 67.5-90 μm toward the center of the material. These data are contained in Table 3 below. Mechanical data of the as received material are shown in Table 4 below. The mean yield strength (“YS”) of the starting material was measured to be 75.3 ksi, and the ultimate tensile strength (“UTS”) was measured to be 90.9 ksi. The Young's modulus (“E”) was 17.75 Msi. and percent elongation was 16.5%.

TABLE 2
Alloying Elements in Example 1 Starting Material

| Chromium | Iron | | Silicon | | Remaining |
|---|---|---|---|---|---|
| (%) | (%) | Nickel (%) | (%) | Copper (%) | Elements (%) |
| 0.37 | <0.01 | 2.20 | 0.48 | 96.94 | 0.004 |

TABLE 3
Grain Size (microns) in Example 1 Starting Material

| | Top (cross | Middle (cross | Bottom (cross | |
|---|---|---|---|---|
| | Section) | section) | section) | Top Face |
| Center | 90.0 | 97.5 | 97.5 | 67.5 |
| Mid Radius | 82.5 | 75.0 | 82.5 | 48.75 |
| Edge | 52.5 | 45.0 | 41.25 | 33.75 |

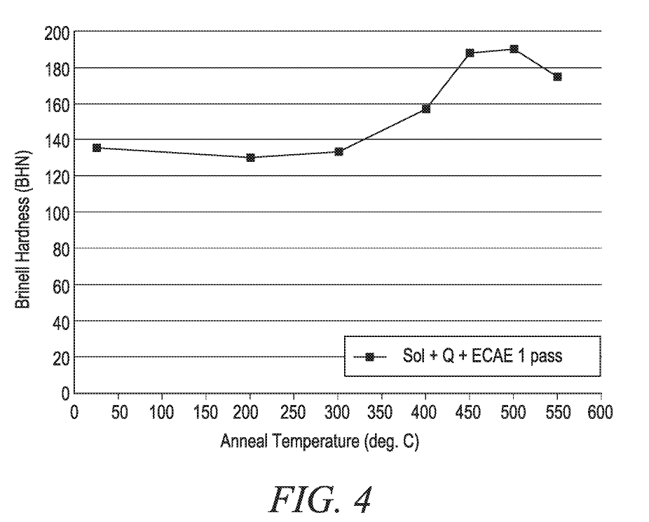

The material was subjected to a solutionizing heat treatment at 900° C. for 8 hours followed by rapid quenching in water. After the solutionizing heat treatment, the starting material strength was substantially reduced due to the dissolution of all soluble precipitates into the matrix. As shown in Table 4, the tensile strength was reduced from an initial 90.9 ksi to 39.4 ksi, and the yield strength was reduced from 75.3 ksi to 18.8 ksi. The corresponding Brinell hardness for this material after the solutionizing heat treatment and quenching was 53.4 BHN. The material was then sent through one ECAE pass at 200° C. FIG. 4 illustrates the change in hardness of the C18000 alloy in relation to the annealing temperature used after solutionizing at 900° C. for 8 hours and a single ECAE pass. As illustrated by the first point in FIG. 4, after ECAE the Brinell hardness increased from 53.4 BHN to about 138 BHN. The hardness was measured with the material having undergone no post ECAE annealing, as demonstrated by the x-axis value for the first point in FIG. 4 listing the temperature as 25° C., or room temperature.

TABLE 4
Effect of Solutionizing, ECAE, and Annealing on Example 1 Material

| | Tensile | | Young's | |
|---|---|---|---|---|
| | Strength | Yield Strength | Modulus | Percent |
| | (ksi) | (ksi) | (Msi) | Elongation |
| Material As | 90.9 | 75.3 | 17.75 | 16.5 |
| Received | | | | |
| Solutionizing at | 39.4 | 18.8 | 11.9 | 45.0 |
| 900° C. for 8 hours | | | | |
| 1 ECAE Pass and | 94.8 | 87.35 | 17.55 | 17.0 |
| 450° C. Annealing | | | | |
| 1 ECAE Pass and | 97.7 | 89.0 | 17.85 | 15.5 |
| 500° C. Annealing | | | | |

Post-ECAE annealing (i.e. age hardening) was conducted to find the optimum temperature to obtain the desired precipitation hardening as measured by Brinell hardness. As demonstrated by the highest points on the curve on FIG. 4, for an aging step lasting one hour, starting at 200° C. the resulting hardness increased until the age hardening temperature was between 450° C. and 500° C. for 1 hour, and then the hardness begins to decrease with further increases in temperature.

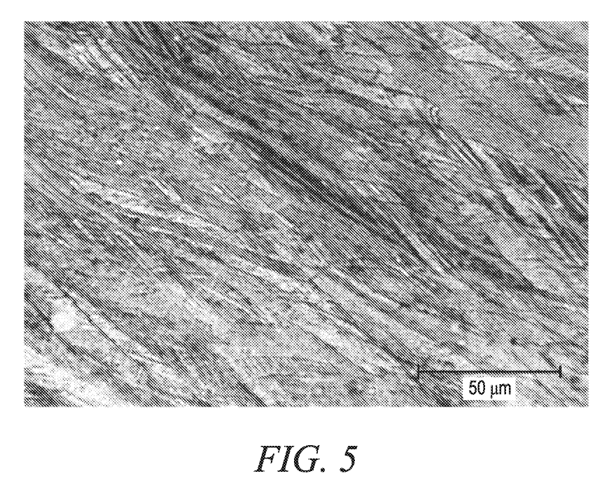

If the annealing temperature exceeds 550° C., hardness starts to decrease substantially. FIG. 5 shows an optical microscopy photograph at 100 time magnification of a C18000 sample after solutionizing at 900° C. for 8 hours, 1 ECAE pass, and annealing at 500° C. for 1 hour. As shown in FIG. 5, optical microscopy indicated a deformed microstructure after annealing up to 500° C. The first signs of grain growth are visible at 550° C., which may explain the hardness decrease at that temperature, shown in FIG. 4. Further analysis indicates that the main soluble precipitates in this mixture are chromium silicides (Cr₃Si or Cr₅Si₂) and Nickel silicides (Ni₂Si).

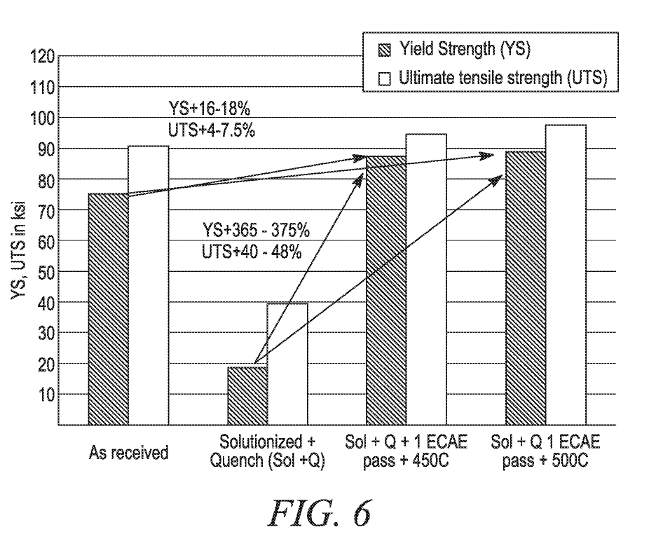

Tensile testing was conducted on the material after being subjected to post-ECAE annealing at 450° C. and 500° C. Data contained in Table 4 above and illustrated in FIG. 6 show that this process was successful in increasing the yield strength and ultimate tensile strength. For example, in a sample that underwent solutionizing at 900° C. for one hour, followed by quenching and one ECAE pass, the ultimate tensile strength increased from 90.9 ksi for the material as received, to 94.8 ksi after aging at 450° C., and 97.7 ksi after aging at 500° C. For this same material, the yield strength increased from 75.3 ksi in the material as received, to 87.35 ksi after aging at 450° C., and 89.0 ksi after aging at 500° C.

It has been found that materials treated using this process maintain this strength level at high temperatures, for example at 450° C. to 500° C., which makes this material particularly suitable for high powered sputtering and high temperature bonding. It is also possible to replace the post ECAE heat aging or annealing step by combining it or replacing it with a bonding step at 450° C. to 500° C. and obtaining the same results. In some instances this may decrease the total processing time required.

### Example 2—Effect of Initial Solutionizing and Annealing Temperatures

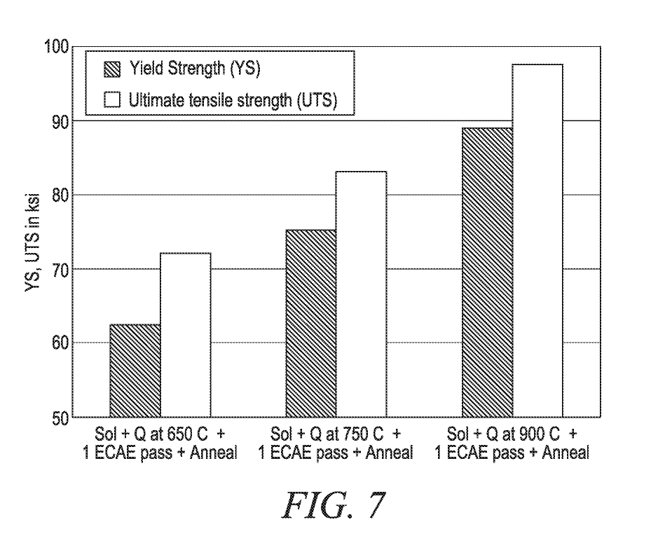

Material from the same starting billet comprised of the same C18000 starting material used in Example 1 was used. In this example, three different pre-ECAE solutionizing heat treatment temperatures were used to compare the effect of the solutionizing temperature on the mechanical properties of a C18000 backing plate after ECAE and age hardening. The three solutionizing samples were subjected to 900° C., 750° C., and 650° C. each for 8 hours followed by quenching with water. All three samples were then subjected to a single ECAE pass at 200° C. and further annealed to optimize the strength. A graph of the results is illustrated in FIG. 7, and the data are tabulated in Table 5. As shown in FIG. 7, the highest tensile strength (YS of 89 ksi: UTS of 97.7 ksi) was obtained when using a pre-ECAE solutionizing temperature of 900° C.

TABLE 5
Effect of Solutionizing Temperature on Example 2
Material Ultimate Tensile Strength

| Pre-ECAE Solutionizing | Max Yield Strength | Max Tensile Strength |
|---|---|---|
| Temperature (° C.) | (ksi) | (ksi) |
| 650 | 62.4 | 72.1 |
| 750 | 75.2 | 83.1 |
| 900 | 89.0 | 97.7 |

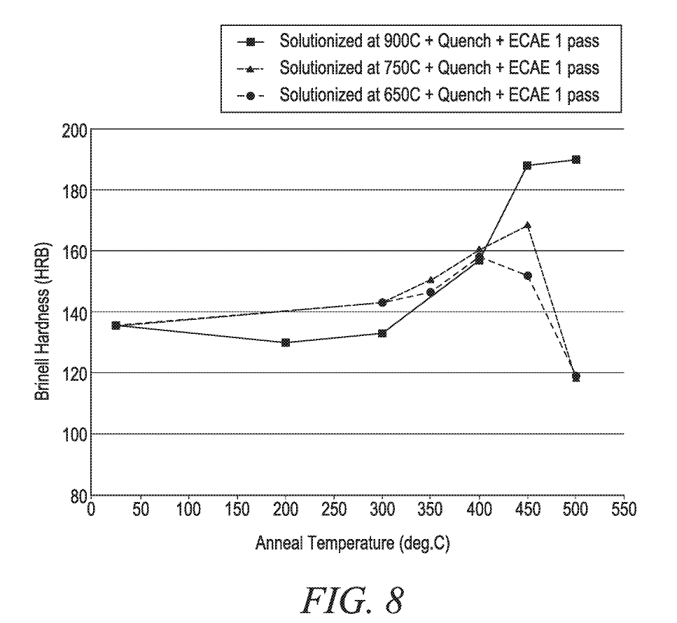

Hardness as a function of both solutionizing temperature and annealing temperature was determined for each sample by also conducting annealing steps at various temperatures ranging from 25° C. up to 500° C. The results of the hardness tests are illustrated in FIG. 8, which simultaneously compares the effect of both solutionizing temperature and annealing temperature on the C18000 material hardness. These data illustrate that the highest achieved hardness and strength is attained with an initial solutionizing temperature of 900° C. for eight hours, followed by a single ECAE pass, and annealing at 500° C.

As shown in FIG. 8, the initial solutionizing treatment is an important parameter in controlling the strength and hardness of the final product. From this example, a recommended range for solutionizing was observed to be 850° C. to 980° C. with a preferred range of 900° C. to 950° C. The total solutionizing time may be at least 30 minutes but not much more than 24 hours, with a preferred value of 1 to 10 hours. Higher temperatures and longer times allow for all soluble alloying elements and precipitates to be dissolved back into solution and be available to form a maximum number of precipitates during the subsequent ECAE and annealing. However, it was also observed that above 950° C. there is the risk of melting the Cu alloy, especially at longer residence times.

### Example 3—Effect of the Number of ECAE Passes

Material from the same starting billet comprised of the same C18000 starting material used in Examples 1 and 2 was used. The initial treatment involved solutionizing the material at 900° C. for 8 hours followed by water quenching. In this example, four different samples were used, two samples subjected to one ECAE pass and one each subjected to two and four ECAE passes. In all cases, the extrusion die and Cu alloy were pre-heated before each ECAE pass to 200° C.

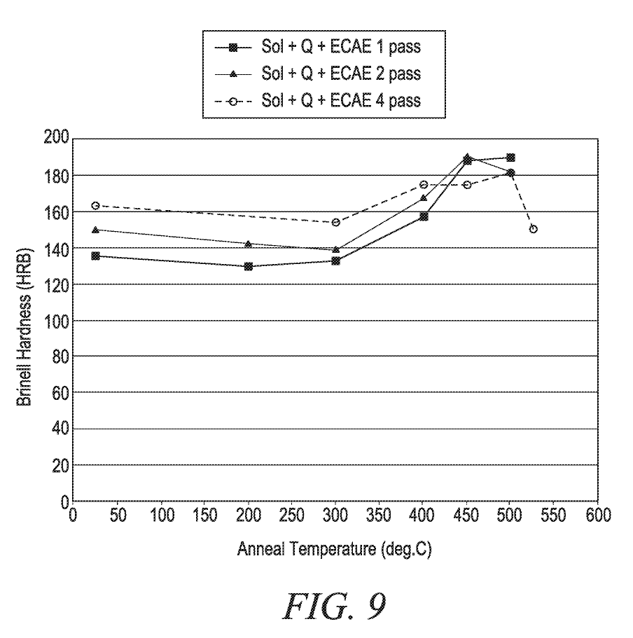

A graph of the results of the Brinell hardness test of the four samples after subsequent annealing is illustrated in FIG. 9. As the data showed, there was an initial increase in hardness as a function of the number of ECAE passes, but this trend is affected by subsequent annealing. For example, when no annealing was used the Brinell hardness increased from 138 BHN after one pass, to 150 BHN after two passes, and to 163 BHN after four passes. This trend is a consequence of the progressive structural refinement and dislocation multiplication imparted by very intense straining. It should be mentioned that, low temperature ECAE at 200° C. also favors some dynamic precipitation of fine particles to occur along with entanglement of those precipitates with multiple grain boundaries and dislocations. The largest increase in hardness was for samples that were subjected to one and two passes with a maximum hardness reached after annealing these two samples between 450° C. and 500° C. for 1 hour.

However, as illustrated in FIG. 9, additional annealing showed that the highest hardness is obtained for one and two passes, but not four passes. Using four ECAE passes gives the highest hardness before annealing is used, but once the material is subject to annealing between 450° C. and 500° C. the hardness no longer increases, and above 500° C. the hardness decreases.

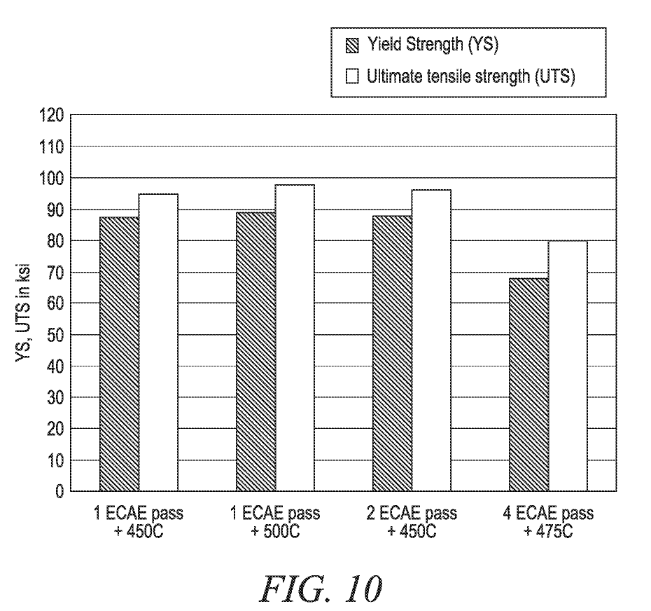

Tensile data are presented in FIG. 10 and Table 6 for one ECAE pass and annealing at 450° C. and 500° C., two ECAE passes and annealing at 450° C. and four ECAE passes and annealing at 475° C. The data illustrate that the values for one and two ECAE passes are similar but there is a clear trend down in values of YS, UTS, and e for four passes at this high temperature range.

TABLE 6
Effect of Number of ECAE Passes and Annealing Temperature
on Example 3 Material

| Number of ECAE | Tensile | | Young's | |
|---|---|---|---|---|
| Passes and Annealing | Strength | Yield Strength | Modulus | Percent |
| Temp | (ksi) | (kis) | (Msi) | Elongation |
| 1 pass and 450° C. | 94.8 | 87.35 | 17.55 | 17.0 |
| 1 pass and 500° C. | 97.7 | 89.0 | 17.85 | 16.5 |
| 2 passes and 450° C. | 96.1 | 87.8 | 17.45 | 17.0 |
| 4 passes and 475° C. | 80.0 | 68.0 | 13.9 | 24.5 |

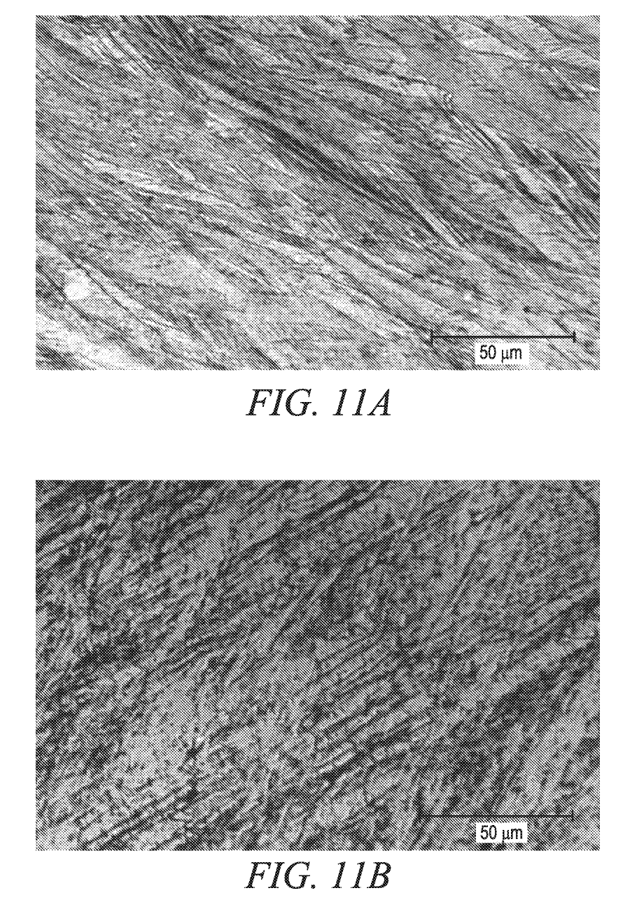

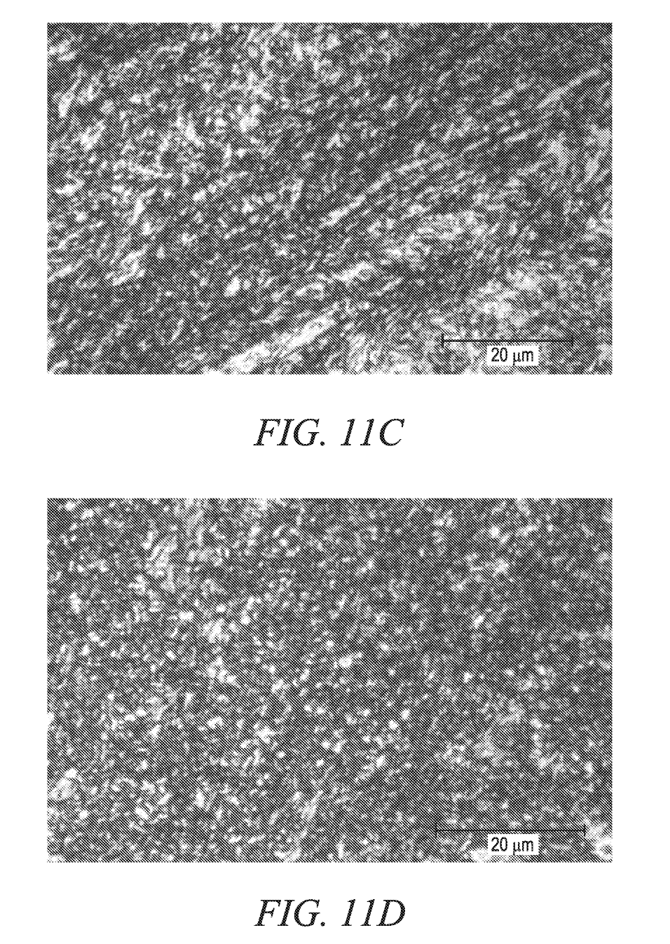

Optical microscopy was used to analyze material processed by the above methods to evaluate the grain texture. The results are illustrated in FIGS. 11A to 11D. FIG. 11A shows material after one ECAE pass and annealing at 500° C. for one hour at 100 times magnification. FIG. 11B shows material after two ECAE passes and annealing at 500° C. for one hour at 100 times magnification. FIG. 11C shows material after four ECAE passes and annealing at 450° C. for one hour at 1000 times magnification. FIG. 11D shows material after four ECAE passes and annealing at 500° C. for one hour at 1000 times magnification.

As shown in FIGS. 11C and 11D, the submicron structure after four passes is not as stable as for one and two passes at 500° C. FIG. 11D demonstrates that for about 25% of the area of the four pass sample, grains have started to grow to extremely fine 1-2 micron structures. These structures reduce the contribution of grain size hardening. In contrast, the structures for one and two ECAE passes do not show any sign of grain growth even up to 500° C. This may illustrate a decrease in strength when using four passes instead of one or two passes.

It also appears that more precipitates are able to grow faster to a non-optimal size for strength and potentially start to dissolve when more free volume is available as, for example, in the space between grains at the grain boundaries. Subjecting the material to four ECAE passes produces more refined structures than one and two passes and therefore has a higher grain boundary volume that facilitates faster kinetics of growth and dissolution of precipitates and therefore results in less desirable high temperature properties. In practice, these finding suggest that is often advantageous to restrict the number of ECAE passes to one or two to get the best properties at high temperatures.

### Example 4—Effect of Rolling on Material after ECAE

A C18000 blank with composition similar to Examples 1-3 was used. Note from Table 6 that the composition in this example has a slightly higher level of Ni and Si than the composition of Examples 1-3. The material was provided by Nonferrous Products Inc. located in Franklin, Ind.

TABLE 7
Alloying Elements in Example 4 Starting Material

| | | Nickel | Silicon | Copper | Remaining |
|---|---|---|---|---|---|
| Chromium (%) | Iron (%) | (%) | (%) | (%) | Elements (%) |
| 0.40 | <0.01 | 2.50 | 0.60 | 96.48 | 0.005 |

The starting material was solutionized at 900° C. for 8 hours then rapidly quenched in water. The measured Brinell hardness was 49.5 BHN. The blank was then cut into smaller pieces that were ECAE extruded for either one pass or two passes at 200° C. Both samples were rolled directly after ECAE using the same rolling process. The total rolling reduction was 60% with no heating of the rolls or alloy material. Rolling such as this is often used after ECAE to get the final shape of a backing plate.

As in previous examples, annealing experiments were conducted at different temperatures to determine the optimum strength and hardness. An optimal temperature range for peak aging to give the highest strength was found to be at 425° C. to 500° C. for both one pass without rolling and one pass with rolling. For two passes without rolling and two passes with rolling, the best range was shifted slightly downward between 425° C. and 450° C. The results of this experiment are contained in Table 8. The data illustrate the main tensile test results for four cases: one ECAE pass followed by annealing at 500° C., one ECAE pass and 60% roll reduction followed by annealing at 450° C.; two ECAE passes followed by annealing at 450° C., two ECAE passes and 60% roll reduction followed by annealing at 425° C.

Sample 2 using one ECAE pass and rolling, followed by annealing at 450° C. gave the highest properties with a yield strength of 100.25 ksi and UTS of 107.45 ksi. The three other samples also show high yield strengths between 91.4 and 93.1 ksi and tensile strengths 101 and 103.1 ksi.

TABLE 8
Effect Number of ECAE Passes and Annealing Temp
on Example 4 Material

| | Number of | Tensile | Yield | Young's | |
|---|---|---|---|---|---|
| | ECAE Passes and | Strength | Strength | Modulus | Percent |
| Sample | Annealing Temp | (ksi) | (kis) | (Msi) | Elongation |
| 1 | 1 pass and 500° C. | 103.1 | 93.0 | 18.5 | 3.6 |
| 2 | 1 pass and 450° C., | 107.45 | 100.25 | 17.2 | 6.75 |
| | and roll | | | | |
| 3 | 2 passes and | 101.1 | 93.1 | 17.85 | 9.25 |
| | 450° C. | | | | |
| 4 | 2 passes and | 101.0 | 91.4 | 15.9 | 12.0 |
| | 425° C. and roll | | | | |

These data indicate that post ECAE rolling is most beneficial after one ECAE pass. After two ECAE passes, rolling has a somewhat neutral effect. Rolling introduces additional dislocations after ECAE that add to strengthening as dislocations get pinned down by precipitates during aging. The effect is most optimal for a low number of ECAE passes (e.g. less than three) and moderate levels of rolling. This is a similar effect to what is observed for higher versus lower number of ECAE passes (see Example 3).

### Detailed EBSD Analysis of Typical Microstructures

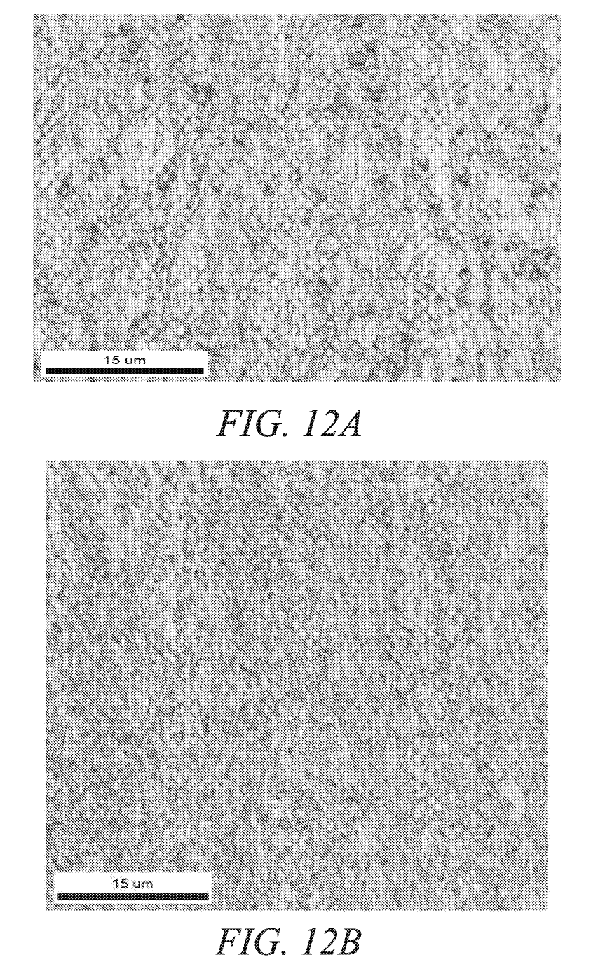

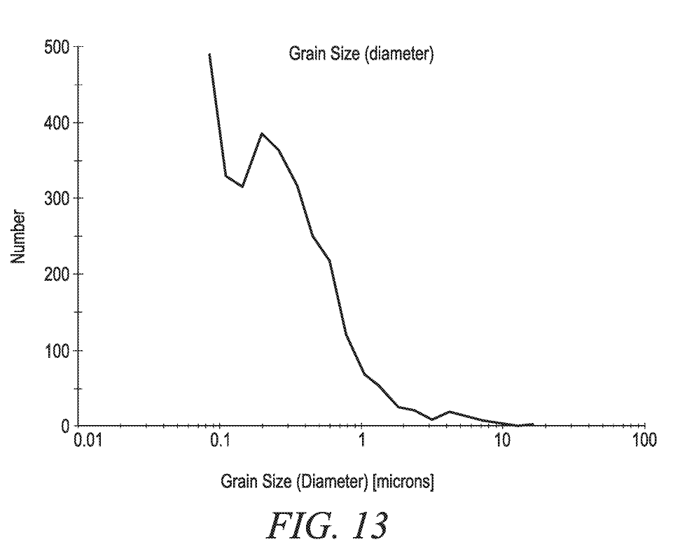

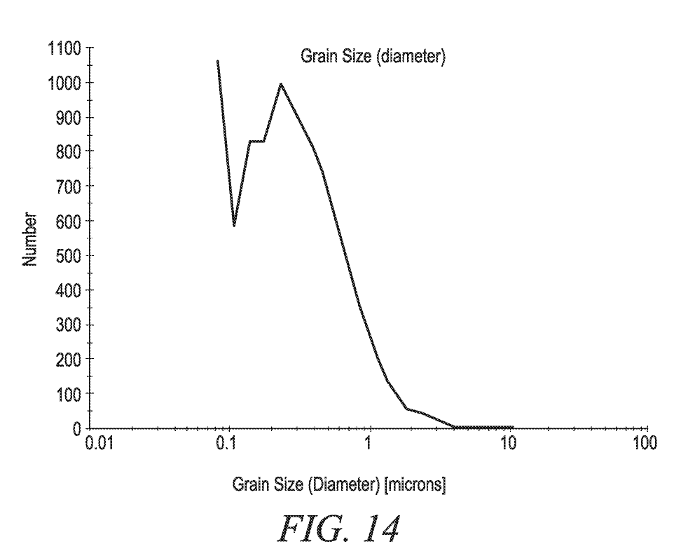

FIGS. 12A, 12B, 13, and 14 show typical microstructures and grain size distribution data after analysis by EBSD microscopy for Samples 2 and 4 of Example 4. The measured average grain size is 0.428 for Sample 2 and 0.383 microns for Sample 4. Table 9 contains the grain size data used to construct the graph shown in FIG. 13. Table 10 contains the grain size data used to construct the graph shown in FIG. 14.

TABLE 9
Number of Grains of Various Diameters for Sample 2
(Illustrated in FIG. 13).
Chart: Grain Size (diameter)
Edge grains included in analysis

| Diameter (microns) | Number |
|---|---|
| 0.0853 | 490 |
| 0.112 | 329 |
| 0.149 | 316 |
| 0.196 | 386 |
| 0.259 | 365 |
| 0.342 | 322 |
| 0.452 | 251 |
| 0.596 | 218 |
| 0.787 | 119 |
| 1.039 | 69 |
| 1.371 | 52 |
| 1.810 | 26 |
| 2.390 | 20 |
| 3.155 | 9 |
| 4.165 | 18 |
| 5.498 | 11 |
| 7.258 | 7 |
| 9.582 | 4 |
| 12.65 | 1 |
| 16.70 | 3 |
| Average Number 0.428 | 0.428376 |
| Standard Deviation Number | 0.927119 |

TABLE 10
Number of Grains of Various Diameters for Sample 4
(Illustrated in FIG. 14).
Chart: Grain Size (diameter)
Edge grains included in analysis

| Diameter (microns) | Number |
|---|---|
| 0.084 | 1060 |
| 0.109 | 571 |
| 0.141 | 829 |
| 0.183 | 829 |
| 0.236 | 1004 |
| 0.305 | 916 |
| 0.395 | 816 |
| 0.510 | 690 |
| 0.660 | 539 |
| 0.854 | 363 |
| 1.104 | 222 |
| 1.427 | 125 |
| 1.846 | 58 |
| 2.386 | 44 |
| 3.086 | 23 |
| 3.990 | 7 |
| 5.160 | 5 |
| 6.672 | 5 |
| 8.628 | 3 |
| 11.16 | 2 |
| Average Number 0.383 | 0.383409 |
| Standard Deviation Number | 0.488874 |

Tables 9 and 10, and FIGS. 13 and 14 illustrate that there are a large number of grains or subgrains that are below 0.1 micron, which is of the same order as the equipment resolution (the step size of EBSD equipment is 0.05 microns). At the scale studied, a few fine dark spots in FIGS. 12A and 12B can be distinguished; they correspond to the precipitates. Most of them are below 0.5 microns in size. Both the grain size and precipitate distribution is uniform.

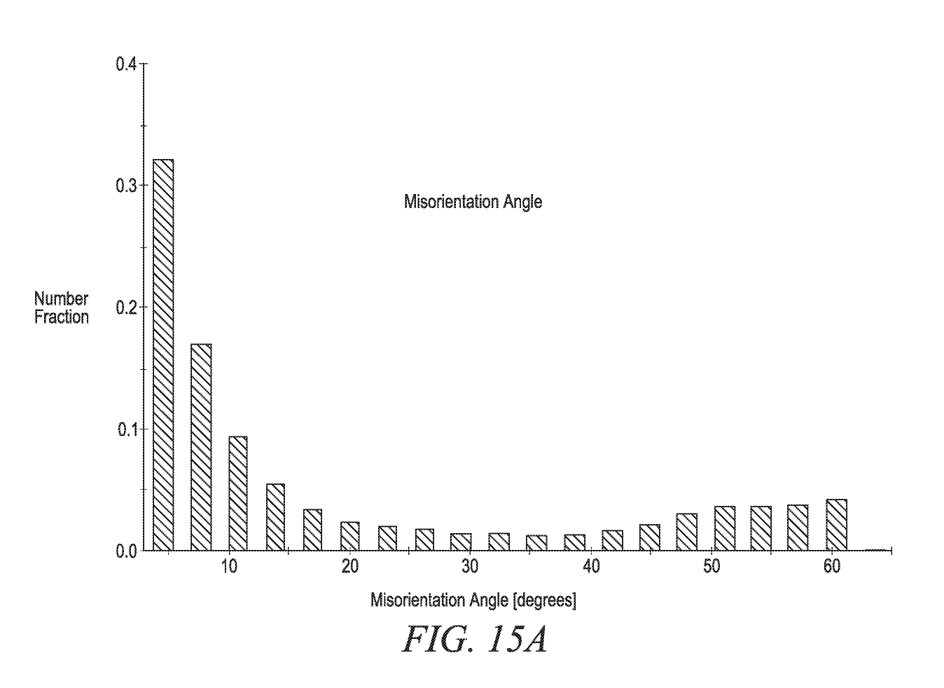

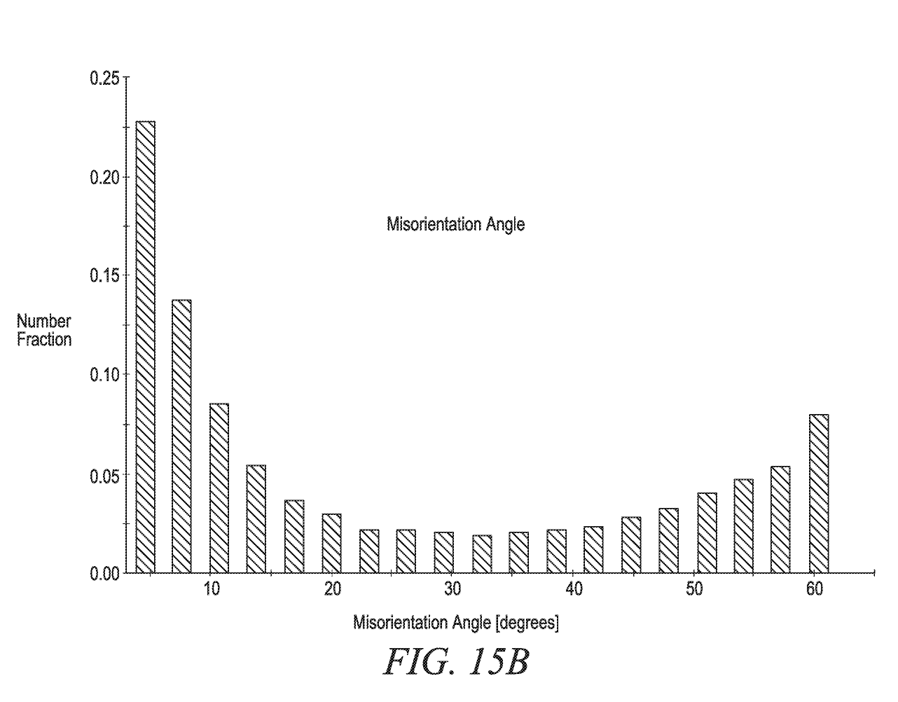

Additional data on the average misorientations between grains is also available by EBSD as shown in FIGS. 15A and 15B. FIG. 15A illustrates the average misorientations from Sample 2 in Example 4 and FIG. 15B illustrates the average misorientations from Sample 4 in Example 4. Table 11 contains the misorientation data used to construct the graph shown in FIG. 15A. Table 12 contains the misorientation data used to construct the graph shown in FIG. 15B.

TABLE 11
Misorientation Angle Data for Sample 2 Graphed in FIG. 15A.
Chart: Misorientation Angle

| Angle (degrees) | Number Fraction |
|---|---|
| 4.55 | 0.321 |
| 7.65 | 0.169 |
| 10.75 | 0.093 |
| 13.85 | 0.053 |
| 16.95 | 0.035 |
| 20.05 | 0.024 |
| 23.15 | 0.020 |
| 26.25 | 0.017 |
| 29.35 | 0.014 |
| 32.45 | 0.014 |
| 35.55 | 0.013 |
| 38.65 | 0.013 |
| 41.75 | 0.016 |
| 44.85 | 0.0208 |
| 47.95 | 0.0292 |
| 51.05 | 0.0355 |
| 54.15 | 0.0349 |
| 57.25 | 0.0377 |
| 60.35 | 0.0413 |
| 63.45 | 0.00164 |
| Average Number | 19.52 |

TABLE 12
Misorientation Angle Data for Sample 4 Graphed in FIG. 15B.
Chart: Misorientation Angle

| Angle (degrees) | Number Fraction |
|---|---|
| 4.55 | 0.228 |
| 7.65 | 0.137 |
| 10.75 | 0.0858 |
| 13.85 | 0.0542 |
| 16.95 | 0.0365 |
| 20.05 | 0.0297 |
| 23.15 | 0.0217 |
| 26.25 | 0.0214 |
| 29.35 | 0.0202 |
| 32.45 | 0.0188 |
| 35.55 | 0.0198 |
| 38.65 | 0.0219 |
| 41.75 | 0.0233 |
| 44.85 | 0.0276 |
| 47.95 | 0.0323 |
| 51.05 | 0.0410 |
| 54.15 | 0.0472 |
| 57.25 | 0.0532 |
| 60.35 | 0.0799 |
| 63.45 | 0.000484 |
| Average Number | 24.9542 |

Table 13 compares the values for Samples 2 and 4 of Example 4. As shown in Table 13. Sample 2 has lower average misorientations than Sample 4. Sample 2 corresponds to the lower number of ECAE passes. This means less energy and less free volume is present along grain boundaries for Sample 2, which in turn influences precipitation dynamics. For instance, there is less volume at grain boundaries and less energy available for precipitate growth which makes the material more thermally stable at peak aging conditions since precipitate growth corresponds to a decrease in strength compared to the peak aged condition that has optimal mechanical properties. This could explain why a lower number of passes promotes more stable properties.

TABLE 13
Effect of Current Method on Grain Size and Mean Misorientation

| Number of ECAE passes and | Grain Size | Mean Misorientation |
|---|---|---|
| Annealing Temperature | (microns) | (degrees) |
| 1 Pass, 450° C. Anneal, and Roll | 0.428 | 19.51 |
| 2 Pass, 425° C. Anneal, and Roll | 0.380 | 24.95 |

### Example 5—Effect of Current Methods on Electrical Properties

The same initial material from Example 4 was subjected to solutionizing at 900° C. for 8 hours, quenched, then sent through one ECAE pass, followed by 60% rolling and an additional annealing step at 450° C. for one hour. As shown in Table 14, electrical resistivity was 4.35 μΩ-cm, which is equivalent to electrical conductivity of 39.6% IACS compared to 44% IACS for the initial as received commercial condition. What this showed was that the material after processing is slightly less conductive and less prone to the creation of Eddy currents generated by the magnetic field ring during sputtering. Eddy currents can be detrimental to target performance by causing a higher incidence of DC power faults.

TABLE 14
Effect of Method on Electrical Conductivity and Resistivity

| | Electrical | |
|---|---|---|
| Number of ECAE passes and | Conductivity | Electrical Resistivity |
| Annealing Temperature | (% IACS) | (μΩ-cm) |
| Material as received | 44.0 | 3.92 |
| 2 Pass, 425° C. Anneal, and Roll | 39.6 | 4.35 |

### Example 6—Comparison of Strength at High Anneal Temperature

A comparison of the effect of three annealing temperatures is contained in Table 15 for a number of alloys, including some commercially available alloys to compare to materials that were made using the methods of the present disclosure. Table 15 compares data for tensile strength after annealing at 250° C., 350° C., and at 450° C.

TABLE 15
Effect of Annealing Temperature on Various Alloys

| | | Yield Strength | Yield Strength | Yield Strength |
|---|---|---|---|---|
| | | After Anneal at | After Anneal at | After Anneal at |
| | | 250° C. (ksi) | 350° C. (ksi) | 450° C. (ksi) |
| Commercially | Standard Al 2024 T8 | 39.0 | 16.7 | 11.0 |
| Available | Standard CuCr | 47.0 | 42.0 | 37.0 |
| | ECAE Cu 1% Al | 69.0 | 31.1 | 29.3 |
| | ECAE Cu 0.5% Sn | 85.0 | 69.0 | 37.3 |
| | ECAE Cu 0.75% Ag | 69.0 | 62.0 | 34.8 |
| | ECAE Cu 2.6% Mn | 89.5 | 79.5 | 39.3 |
| | ECAE Cu 0.5% Ti | 75.0 | 61.6 | 57.2 |
| | Standard C18000 | 75.3 | 75.3 | 75.3 |
| Current | ECAE C18000 1 Pass | 87.0-93.0 | 87.0-93.0 | 87.0-93.0 |
| Embodiments | ECAE C18000 1 pass | 100.25 | 100.25 | 100.25 |
| | and roll | | | |
| | ECAE C18000 2 | 93.1 | 93.1 | 93.1 |
| | passes | | | |

It can be shown that the copper alloy composition processed according to the methods of the current disclosure with one or two ECAE passes possess the best high temperature properties in the given temperature range. The effect is most dramatic at 350° C. as well as 450° C. Some of these properties were valid up to 500° C. as illustrated in Example 4. It is also likely that adding more elements; for example Ni, Si, Zr, or Be, that improve thermal properties in C18000 may further improve the results.

Various modifications and additions can be made to the exemplary embodiments discussed without departing from the scope of the instant disclosure. For example, while the embodiments described above refer to particular features, the scope of the instant disclosure also includes embodiments having different combinations of features and embodiments that do not include all of the above described features.

1-10. (canceled)

11. A method of forming a high strength backing plate for use with a sputtering target comprising:
solutionizing a first metal material at a temperature between about 850 and 950 degrees Celsius;
subjecting the first metal material to equal channel angular extrusion; and
aging the first metal material at a temperature of between about 400 and about 550 degrees Celsius.

12. The method of claim 11, wherein the solutionizing is conducted for between one and eight hours.

13. The method of claim 11, wherein the solutionizing is conducted for at least eight hours and not more than twenty four hours.

14. The method of claim 11, wherein subjecting the first metal material to equal channel angular extrusion includes one extrusion pass.

15. The method of claim 11, wherein subjecting the first metal material to equal channel angular extrusion includes at least two extrusion passes.

16. The method of claim 11, wherein aging the first metal material includes aging for at least 30 minutes.

17. The method of claim 11, wherein aging the first metal material includes aging for between about 30 minutes and about one hour.

18. The method of claim 11, wherein aging the first metal material includes aging for between about one hour and about eight hours.

19. The method of claim 11, wherein aging the first metal material is carried out concurrently with bonding the first metal material to a second metal material.

20. The method of claim 11, wherein the first metal material comprises between about 1.5 wt % and 6.0 wt % nickel, between about 0.25 wt % and 2.0 wt % silicon, between about 0.10 wt % and 2.0 wt % chromium, and the balance copper.

21. The method of claim 11, wherein the first metal material includes at least one of copper, chromium, silicon, nickel, silver, manganese, vanadium, iron, zirconium, beryllium, magnesium, tin, scandium, titanium, cobalt, niobium, tungsten, zinc, dispersed oxides, carbon, and combinations thereof.

22. The method of claim 11, wherein the first metal material has an electrical resistivity of between about 2.5 and 6.0 μΩ-cm.

23. A sputtering target backing plate composition comprising:
a first metal material having
a 0.2% offset yield strength greater than 82.5 ksi; and
a tensile strength greater than 90 ksi,
up to a temperature of at least 425 degrees Celsius.

24. The backing plate composition of claim 23, wherein the first metal material comprises between about 1.5 wt % and 6.0 wt % nickel, between about 0.25 wt % and 2.0 wt % silicon, between about 0.10 wt % and 2.0 wt % chromium, and the balance copper.

25. The backing plate composition of claim 23, wherein the first metal material includes at least one of copper, chromium, silicon, nickel, silver, manganese, vanadium, iron, zirconium, beryllium, magnesium, tin, scandium, titanium, cobalt, niobium, tungsten, zinc, dispersed oxides, carbon, and combinations thereof.

26. The backing plate composition of claim 23, wherein the first metal material has an average grain size of between about 0.4 and about 0.5 microns.

27. The backing plate composition of claim 23, wherein the first metal material has an average grain size of between about 0.3 and about 0.4 microns.

28. The backing plate composition of claim 23, wherein the first metal material has an average grain misorientation of between about 18.00 and about 22.00 degrees.

29. The backing plate composition of claim 23, wherein the first metal material has an average grain misorientation of between about 22.00 and about 28.00 degrees.

30. The backing plate composition of claim 23, wherein the first metal material has an electrical resistivity of between about 2.5 and 6.0 μΩ-cm.
